(19) United States
(12) Patent Application Publication
(10) Pub. No.: US 2025/0110182 A1
(43) Pub. Date: Apr. 3, 2025

(54) BATTERY MONITORING USING TELEMATICS

(71) Applicant: Caterpillar Inc., Peoria, IL (US)

(72) Inventors: Matthew BECKNER, Chillicothe, IL (US); Wellington Y. KWOK, Dunlap, IL (US); Jinhui SUN, Dunlap, IL (US); James Joshua DRISCOLL, Dunlap, IL (US)

(73) Assignee: Caterpillar Inc., Peoria, IL (US)

(21) Appl. No.: 18/478,217

(22) Filed: Sep. 29, 2023

(51) Int. Cl. G01R 31/392; B60L 58/12; B60L 58/16; G01R 31/367; G01R 31/382

(52) U.S. Cl. CPC G01R 31/392; B60L 58/12; B60L 58/16; G01R 31/367; G01R 31/382

(57) ABSTRACT

An electric vehicle may include a battery module including a battery cell, and one or more controllers. The controller(s) may be configured to detect a charging of the battery cell. The controller(s) may be configured to obtain, based on detection of the charging, charging data associated with the charging. The charging data may indicate at least one of a voltage, a current, or a temperature associated with the battery cell during the charging. The controller(s) may be configured to transmit the charging data to a device remote from the electric vehicle to cause the device to estimate an SOH, an RUL, and/or a performance indicator for the battery cell based on the charging data. The controller(s) may be configured to receive an indication, based on the performance indicator, that indicates the SOH and/or the RUL, or that indicates a request for additional data associated with the battery cell.

### TECHNICAL FIELD

The present disclosure relates generally to batteries and, for example, to battery monitoring using telematics.

### BACKGROUND

A machine may include one or more battery packs to provide power to components of the machine, such as lights, computer systems, and/or a motor, among other examples. A battery pack may be associated with a modular design that includes multiple battery modules. A battery module may include multiple battery cells. Over the life of a battery cell, which can last several years, the energy provided by the battery cell decreases until replacement of the battery cell is needed. Accordingly, a state of health (SOH) of the battery cell can be estimated and monitored over time to identify when the battery cell has reached an end of its useful life. Significant computing power may be needed to accurately estimate the SOH of a battery cell, battery module, and/or battery pack. However, controllers (e.g., electronic control modules (ECMs)) of a machine powered by one or more battery packs, such as a main machine controller and/or one or more controllers of a battery management system of the machine, may lack such computing power, thereby leading to less accurate SOH estimation. Less accurate SOH estimation may lead to the machine's battery being replaced less frequently than needed, thereby affecting a performance of the battery and the machine, and/or more frequently than needed, thereby causing excessive machine downtime and increasing maintenance costs for the machine.

U.S. Patent Application Publication No. 20210373082 (the '082 publication) relates to electric and hybrid vehicles, and to determining an SOH of an electrical energy store. The '082 publication discloses that vehicle parameters, predicted vehicle parameters, and an instantaneous SOH are transmitted to a central unit and processed with the aid of a data-based SOH model in order to predict an SOH of a vehicle battery based on the predicted vehicle parameters. Training the data-based SOH model of the '082 publication to accurately estimate SOH may require massive amounts of data that is potentially unavailable. Moreover, a data-based model may produce less accurate outputs than a physics-based model. Furthermore, the '082 publication does not disclose collecting data and performing SOH estimation during charging of a vehicle's battery, which may improve a relevancy of the data and lead to more accurate SOH estimation.

The monitoring system of the present disclosure solves one or more of the problems set forth above and/or other problems in the art.

### SUMMARY

A device may include one or more memories, and one or more processors, communicatively coupled to the one or more memories. The one or more processors may be configured to receive, from an electric vehicle remote from the device, charging data associated with a charging of a battery cell of the electric vehicle, the charging data indicating at least one of a voltage, a current, or a temperature associated with the battery cell during the charging. The one or more processors may be configured to retrieve historical data, associated with the battery cell, including one or more of: historical charging data, historical SOH data, historical remaining useful life (RUL) data, or historical performance indicator data. The one or more processors may be configured to determine, using a physics-based model and based on the charging data and the historical data, one or more of an SOH for the battery cell, an RUL for the battery cell, or a performance indicator for the battery cell. The one or more processors may be configured to determine whether the performance indicator is indicative of a faultiness of the battery cell. The one or more processors may be configured to transmit, to the electric vehicle, an indication that indicates at least one of the SOH or the RUL, responsive to a determination that the performance indicator is not indicative of the faultiness of the battery cell, or that indicates a request for additional data associated with the battery cell responsive to a determination that the performance indicator is indicative of the faultiness of the battery cell.

A method may include receiving, by a device and from an electric vehicle remote from the device, charging data associated with a charging of a battery cell of the electric vehicle, the charging data indicating at least one of a voltage, a current, or a temperature associated with the battery cell during the charging. The method may include determining, using a physics-based model and based on the charging data, one or more of an SOH for the battery cell, an RUL for the battery cell, or a performance indicator for the battery cell. The method may include determining whether the performance indicator is indicative of a faultiness of the battery cell. The method may include transmitting, to the electric vehicle, an indication that indicates at least one of the SOH or the RUL, responsive to a determination that the performance indicator is not indicative of the faultiness of the battery cell, or that indicates a request for additional data associated with the battery cell responsive to a determination that the performance indicator is indicative of the faultiness of the battery cell.

An electric vehicle may include a battery module including a battery cell, and one or more controllers. The one or more controllers may be configured to detect a charging of the battery cell. The one or more controllers may be configured to obtain, based on detection of the charging of the battery cell, charging data associated with the charging of the battery cell, the charging data indicating at least one of a voltage, a current, or a temperature associated with the battery cell during the charging of the battery cell. The one or more controllers may be configured to transmit the charging data to a device remote from the electric vehicle to cause the device to estimate one or more of an SOH for the battery cell, an RUL for the battery cell, or a performance indicator for the battery cell based on the charging data. The one or more controllers may be configured to receive an indication, based on the performance indicator, that indicates at least one of the SOH or the RUL, or that indicates a request for additional data associated with the battery cell.

### BRIEF DESCRIPTION OF THE DRAWINGS

FIG. 1 is a diagram of an example battery pack.

FIG. 2 is a diagram of an example monitoring system.

FIG. 3 is a flowchart of an example process associated with battery monitoring using telematics.

### DETAILED DESCRIPTION

This disclosure relates to battery monitoring using telematics, and is applicable to any machine application that uses power provided by a battery. For example, the machine may perform an operation associated with an industry, such as mining, construction, farming, transportation, or any other industry. For example, the machine may be an electric vehicle, an electric work machine (e.g., a compactor machine, a paving machine, a cold planer, a grading machine, a backhoe loader, a wheel loader, a harvester, an excavator, a motor grader, a skid steer loader, a tractor, and/or a dozer), or an energy storage system, among other examples. The battery monitoring described herein is applicable to a battery cell, a battery module, and/or a battery pack. As used herein, “battery cell,” “battery,” and “cell” may be used interchangeably.

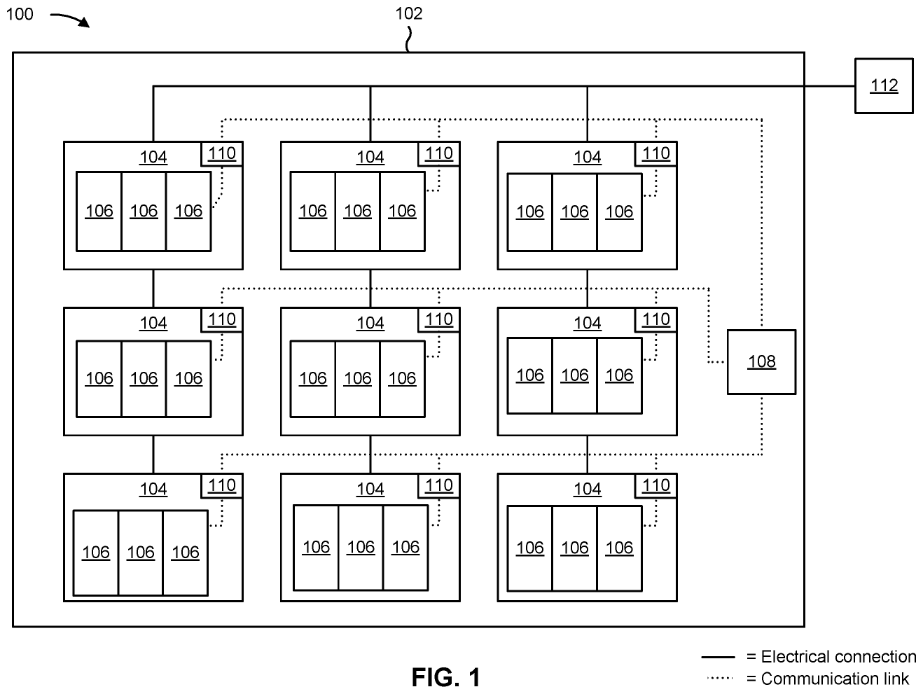

FIG. 1 is a diagram of an example battery pack 100. The battery pack 100 may include a battery pack housing 102, one or more battery modules 104, and one or more battery cells 106. The battery pack 100 includes a battery pack controller 108 associated with storing information and/or controlling one or more operations associated with the battery pack 100. Each battery module 104 includes a module controller 110 associated with storing information and/or controlling one or more operations associated with the battery module 104.

The battery pack 100 may be associated with a component 112. The component 112 may be powered by the battery pack 100. For example, the component 112 can be a load that consumes energy provided by the battery pack 100, such as an estimation system or an electric motor, among other examples. As another example, the component 112 provides energy to the battery pack 100 (e.g., to be stored by the battery cells 106). In such examples, the component 112 may be a power generator, a solar energy system, and/or a wind energy system, among other examples.

The battery pack housing 102 may include metal shielding (e.g., steel, aluminum, or the like) to protect elements (e.g., battery modules 104, battery cells 106, the battery pack controller 108, the module controllers 110, wires, circuit boards, or the like) positioned within battery pack housing 102. Each battery module 104 includes one or more (e.g., a plurality of) battery cells 106 (e.g., positioned within a housing of the battery module 104). Battery cells 106 may be connected in series and/or in parallel within the battery module 104 (e.g., via terminal-to-busbar welds). Each battery cell 106 is associated with a chemistry type. The chemistry type may include lithium ion (Li-ion) (e.g., lithium ion polymer (Li-ion polymer), lithium iron phosphate (LFP), and/or nickel manganese cobalt (NMC)), nickel-metal hydride (NiMH), or nickel cadmium (NiCd), among other examples.

The battery modules 104 may be arranged within the battery pack 100 in one or more strings. For example, the battery modules 104 are connected via electrical connections, as shown in FIG. 1. The electrical connections may be removable, such as via bolts and/or nuts at one or more terminals on housings of the battery modules 104. The battery modules 104 may be connected in series and/or in parallel. For example, a number of battery modules 104 may be connected in series to provide a particular voltage (e.g., to the component 112). Alternatively, a number of battery modules 104 may be connected in parallel to increase a current and/or a power output of the battery pack 100. The number of battery cells 106 included in each battery module 104, and the number of battery modules 104 included in the battery pack 100 (e.g., and the relative serial and/or parallel connections of the battery cells 106 and/or the battery modules 104) may be associated with the required output power and an intended use of the battery pack 100. For example, any number of battery cells 106 can be included in a battery module 104. Similarly, any number of battery modules 104 can be included in the battery pack 100.

The battery pack controller 108 is communicatively connected (e.g., via a communication link) to each module controller 110. The battery pack controller 108 may be associated with receiving, generating, storing, processing, providing, and/or routing information associated with the battery pack 100. The battery pack controller 108 may also be referred to as a battery pack management device or system. The battery pack controller 108 may communicate with the component 112 and/or a controller of the component 112, may control a start-up and/or shut-down procedure of the battery pack 100, may monitor a current and/or voltage of a string (e.g., of battery modules 104), and/or may monitor and/or control a current and/or voltage provided by the battery pack 100, among other examples. A module controller 110 may be associated with receiving, generating, storing, processing, providing, and/or routing information associated with a battery module 104. The module controller 110 may communicate with the battery pack controller 108.

The battery pack controller 108 and/or a module controller 110 may be associated with monitoring and/or determining a state of charge (SOC), a state of health (SOH), a depth of discharge (DOD), an output voltage, a temperature, and/or an internal resistance and impedance, among other examples, associated with a battery module 104 and/or associated with the battery pack 100. Additionally, or alternatively, the battery pack controller 108 and/or the module controller 110 may be associated with monitoring, controlling, and/or reporting one or more parameters associated with battery cells 106. The one or more parameters may include cell voltages, temperatures, chemistry types, a cell energy throughput, a cell internal resistance, and/or a quantity of charge-discharge cycles of a battery module 104, among other examples.

The battery pack controller 108 and/or a module controller 110 includes one or more processors and/or one or more memories. A processor may include a central processing unit, a microprocessor, a controller, a microcontroller, a digital signal processor, a field-programmable gate array, an application-specific integrated circuit, and/or another type of processing component. The processor may be implemented in hardware, firmware, or a combination of hardware and software. In some implementations, the processor may include one or more processors capable of being programmed to perform one or more operations or processes described elsewhere herein. A memory may include volatile and/or nonvolatile memory. For example, the memory may include random access memory (RAM), read only memory (ROM), and/or another type of memory (e.g., a flash memory, a magnetic memory, and/or an optical memory). The memory may include internal memory (e.g., RAM, ROM, or a hard disk drive) and/or removable memory (e.g., removable via a universal serial bus connection). The memory may be a non-transitory computer-readable medium. The memory may store information, one or more instructions, and/or software (e.g., one or more software applications) related to the operation of the battery pack 100, a battery module 104, and/or a battery cell 106. The memory may include one or more memories that are coupled (e.g., communicatively coupled) to the processor, such as via a bus. Communicative coupling between a processor and a memory may enable the processor to read and/or process information stored in the memory and/or to store information in the memory.

As indicated above, FIG. 1 is provided as an example. Other examples may differ from what is described with regard to FIG. 1.

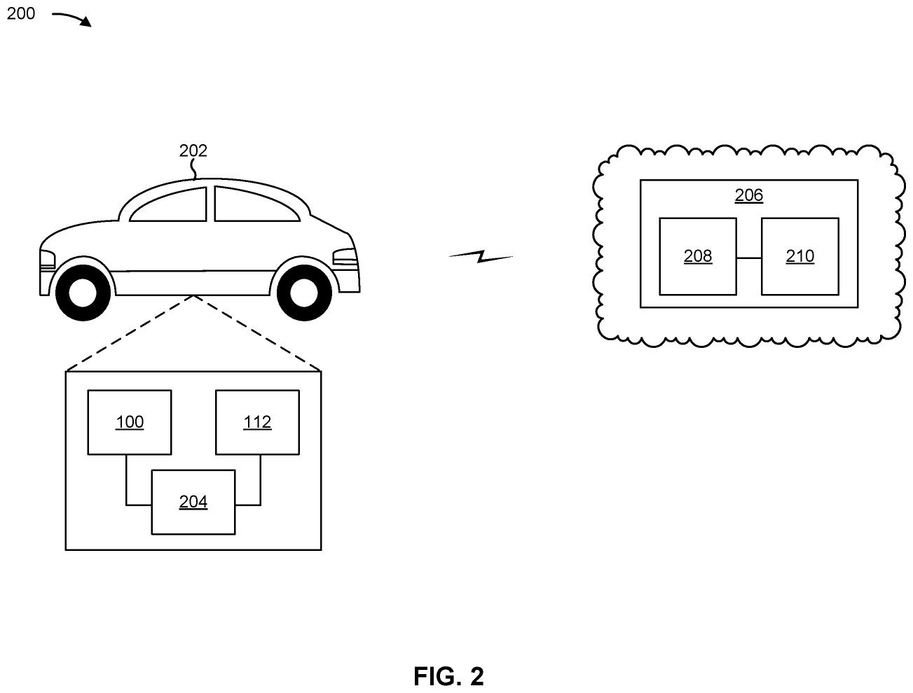

FIG. 2 is a diagram of an example monitoring system 200. The monitoring system 200 may include a machine 202. The machine 202 may be an electric vehicle (e.g., an electric car, an electric work machine, or the like), as shown. The machine 202 includes the battery pack 100 and the component 112 (e.g., an electric motor of the vehicle). The machine 202 also includes a controller 204 (e.g., an ECM). The controller 204 may be communicatively connected to the battery pack controller 108, the module controller(s) 110, and/or a controller associated with the component 112. The controller 204 may include one or more processors and/or one or more memories, as described above. Operations described herein as being performed by the machine 202 may be performed individually or collectively by one or more of the controllers of the machine 202 (e.g., the controller 204, the battery pack controller 108, and/or one or more module controllers 110).

The monitoring system 200 may include an estimation system 206. The estimation system 206 may include one or more computing devices (e.g., one or more server devices). For example, the estimation system 206 may include one or more processors 208 and/or one or more memories 210, as described above. Operations described herein as being performed by the estimation system 206 may be performed individually or collectively by the one or more processors 208 and/or the one or more memories 210. A computing power of the estimation system 206 may be greater than a computing power of the controllers of the machine 202 (e.g., individually or combined). In some examples, the estimation system 206 may implement one or more data structures, such as one or more databases, used to store historical battery monitoring data.

The machine 202 and the estimation system 206 may be remote from each other (e.g., the machine 202 and the estimation system 206 are non-co-located). In other words, the estimation system 206 is not located on board the machine 202. For example, the estimation system 206 may be cloud based. Accordingly, the machine 202 and the estimation system 206 may communicate via the Internet, via a Bluetooth connection, via a local WiFi connection, or the like. For example, the machine 202 may wirelessly communicate with the estimation system 206.

The machine 202 may detect a charging of a battery cell 106. For example, the charging may be of a battery module 104 that includes the battery cell 106 and/or may be of the battery pack 100. The machine 202 may detect the charging of the battery cell 106 based on detecting that the machine 202 is plugged into an electrical power source. Additionally, or alternatively, the machine 202 may detect the charging of the battery cell 106 based on detecting a charging current to the battery pack 100.

Based on detection of the charging of the battery cell 106 (e.g., of the battery module 104 that includes the battery cell 106 and/or the battery pack 100), the machine 202 may obtain charging data associated with the charging of the battery cell 106. The charging data may relate to one or more parameters associated with the battery cell 106 during the charging. For example, the charging data may indicate a voltage, a current, and/or a temperature associated with the battery cell 106 during the charging.

The machine 202 may obtain the charging data from one or more sensors associated with (e.g., connected to) the battery cell 106. For example, the one or more sensors may include a voltage sensor, a current sensor (e.g., a Hall sensor, a magnetoresistive sensor, or the like), and/or a temperature sensor (e.g., an integrated circuit temperature sensor, a thermistor, a thermocouple, a resistance temperature detector, or the like). The voltage sensor and/or the current sensor may be electrically connected to terminals of the battery cell 106. The charging data may include a single data point (e.g., based on a single sample or an aggregation, such as an average, of multiple samples) for each of the parameters (e.g., a single voltage value, a single current value, and/or a single temperature value). Alternatively, the charging data may include a data series for each of the parameters (e.g., a series of voltage values, a series of current values, and/or a series of temperature values).

In some implementations, the machine 202 may obtain the charging data in connection with a normal charging operation for the machine 202. For example, the charging data may be obtained without modification of the charging operation used by the machine 202. Additionally, or alternatively, the machine 202 may obtain the charging data in connection with a charging pulse (e.g., a custom charging pulse). For example, during the charging (e.g., based on detection of the charging), the machine 202 may cause a charging pulse to be applied to the battery cell 106 for a time period (e.g., 2 seconds, 5 seconds, or the like). Here, to obtain the charging data, the machine 202 may obtain first charging data during the time period (e.g., when current is on to the battery cell 106) and second charging data outside of the time period (e.g., when current is off to the battery cell 106). The first charging data and the second charging data may provide an improved representation of ion movement of the battery cell 106 (e.g., relative to charging data obtained only when the current is on to the battery cell 106).

In some implementations, the machine 202 may obtain the charging data in connection with multiple charging pulses. For example, during the charging (e.g., based on detection of the charging), the machine 202 may cause multiple individual charging pulses to be applied to the battery cell 106, and the machine 202 may obtain charging data in connection with each charging pulse in a similar manner as described above. In some examples, each charging pulse may occur at a different (e.g., different by at least 5% or at least 10%) SOC of the battery cell 106.

In some implementations, the machine 202 may obtain the charging data using electrochemical impedance spectroscopy (EIS) (e.g., the charging data may not relate to the charging of the battery cell 106). For example, the machine 202 may inject a diagnostic signal (e.g., a small-amplitude alternating current signal that sweeps over multiple frequencies) to the battery cell 106, and the machine 202 may receive a response signal (e.g., a voltage response spectrum to the diagnostic signal) indicating the charging data. The machine 202 may include an EIS component to perform the EIS.

Additionally, the machine 202 may obtain usage data associated with one or more previous (e.g., previous to the charging of the battery cell 106) dischargings of the battery cell 106 (e.g., previous dischargings of the battery module 104 that includes the battery cell 106, a string of battery modules 104 that includes the battery module 104, and/or the battery pack 100). The usage data may relate to the one or more parameters of the battery cell 106 (e.g., of the battery module 104, the string of battery modules 104, and/or the battery pack 100) during the discharging(s). For example, the usage data may indicate a voltage and/or a current of the battery cell 106 (e.g., of the battery module 104, the string of battery modules 104, and/or the battery pack 100) during the discharging(s). Additionally, or alternatively, the usage data may relate to a charging and/or discharging temperature, a charging and/or discharging rate, a charging and/or discharging duration, and/or a duty cycle of the battery cell 106, the battery module 104, the string of battery modules 104, and/or the battery pack 100. During operation of the machine 202, the usage data may be collected (e.g., using one or more sensors, in a similar manner as described above) and stored by the machine 202. Accordingly, the machine 202 may retrieve the usage data from a storage of the machine 202 (e.g., based on obtaining the charging data).

The machine 202 may transmit, and the estimation system 206 may receive, the charging data and/or the usage data. For example, the machine 202 may transmit the charging data and/or the usage data to the estimation system 206 to cause the estimation system 206 to estimate an SOH, an RUL, and/or a performance indicator associated with the battery cell 106 based on the charging data and/or the usage data (e.g., because the controller(s) of the machine 202 may lack the computing power to perform high-fidelity estimation). As an example, the machine 202 may transmit a request to the estimation system 206 that includes the charging data and/or the usage data. The request may indicate an identifier associated with the machine 202, an identifier associated with the battery cell 106, an identifier associated with the battery module 104, and/or an identifier associated with the battery pack 100. The usage data may relate to a time period between a previous upload to the estimation system 206 and a current upload to the estimation system 206. While the charging data transmitted by the machine 202 is described herein in terms of a single battery cell 106, in practice, the machine 202 may transmit charging data for each battery cell 106 of one or more battery modules 104 and/or of the battery pack 100.

The estimation system 206 may retrieve historical data from a storage (e.g., a data structure, such as a database) for use in estimating the SOH, the RUL, and/or the performance indicator associated with the battery cell 106. The storage may be a cloud-based storage. For example, the estimation system 206 may retrieve the historical data, associated with the battery cell 106, responsive to receiving the charging data and/or the usage data from the machine 202 (e.g., the estimation system 206 may retrieve the historical data based on one or more identifiers indicated in the request). The historical data may indicate historical charging data, historical SOH data, historical RUL data, and/or historical performance indicator data (e.g., one or more of which may be represented in a histogram format). For example, the historical SOH data may indicate one or more previous SOH estimations for the battery cell 106, the historical RUL data may indicate one or more previous RUL estimations for the battery cell 106, and the historical performance indicator data may indicate one or more previous performance indicators for the battery cell 106. Additionally, or alternatively, the historical data may indicate historical usage data associated with the battery cell. For example, the historical usage data may indicate usage data associated with one or more previous uploads from the machine 202 to the estimation system 206. While the historical data retrieved by the estimation system 206 is described herein in terms of a single battery cell 106, in practice, the estimation system 206 may retrieve historical data for each battery cell 106 of one or more battery modules 104 and/or of the battery pack 100.

The estimation system 206 may determine (e.g., estimate) an SOH, an RUL, and/or a performance indicator (e.g., one or more performance indicators) for the battery cell 106 based on the charging data, the usage data, and/or the historical data. The estimation system 206 may store information indicating the charging data, the usage data, the SOH, the RUL, and/or the performance indicator in the storage (e.g., to facilitate their inclusion in historical data used for a subsequent estimation). The estimation system 206 may determine the SOH, the RUL, and/or the performance indicator using a physics-based model. For example, the estimation system 206 may provide the charging data, the usage data, and/or the historical data as an input to the physics-based model, and the physics-based model may output the SOH, the RUL, and/or the performance indicator.

The physics-based model may be based on the particular chemical and material properties of the battery cell 106. Moreover, the physics-based model may be based on porous electrode theory (e.g., with respect to the particular chemical and material properties of the battery cell 106). The physics-based model may be a machine learning model. For example, the machine learning model may be configured to estimate the SOH, the RUL, and/or the performance indicator using information about physics principles relating to the battery cells 106 (e.g., porous electrode theory based on the particular chemical and material properties of the battery cells 106). As an example, the machine learning model may be configured with (e.g., using hyperparameters, training data, constraints, regularization terms, or the like) one or more physics equations (e.g., based on porous electrode theory with respect to the particular chemical and material properties of the battery cells 106). The machine learning model may be a regression model, a neural network model (e.g., a convolutional neural network (CNN) model, a recurrent neural network (RNN) model, or the like), a decision tree model, and/or a random forest model, among other examples. The estimation system 206 may store outputs of the physics-based model (e.g., relating to the machine 202 or one or more other machines), and over time the estimation system 206 may refine (e.g., tune) the physics-based model based on the outputs.

The estimation system 206 may determine whether the performance indicator (e.g., one or more performance indicators) is indicative of a faultiness of the battery cell. The performance indicator may indicate lithium plating in the battery cell 106, a thermal runaway probability of the battery cell 106, or the like. The battery cell 106 may be faulty if the performance indicator indicates a poor health of the battery cell 106 (e.g., the performance indicator satisfies a threshold and/or the performance indicator has deviated from an initial state (or previous state) by a threshold amount or percentage). A faultiness of the battery cell 106 may be a defect that has been produced through normal usage. A faultiness of the battery cell 106 may be reflected by capacity loss, reduced charging rate (e.g., longer charging time), reduced discharging voltage and/or current, overheating, swelling, and/or thermal runaway, among other examples.

While the SOH, the RUL, and/or the performance indicator determined by the estimation system 206 is described herein in terms of a single battery cell 106, in practice, the estimation system 206 may determine an SOH, an RUL, and/or a performance indicator for each battery cell 106 of one or more battery modules 104 and/or of the battery pack 100. Moreover, the estimation system 206 may determine an SOH, an RUL, and/or a performance indicator for a battery module 104 and/or a battery pack 100. The estimation system 206 may determine an SOH, an RUL, and/or a performance indicator for a battery module 104 as an aggregation of SOHs, RULs, and/or performance indicators associated with battery cells 106 of the battery module 104. Similarly, the estimation system 206 may determine an SOH, an RUL, and/or a performance indicator for a battery pack 100 as an aggregation of SOHs, RULs, and/or performance indicators associated with battery modules 104 of the battery pack 100 and/or associated with battery cells 106 of the battery pack 100. The aggregation may be an average value, a median value, a mode value, a lowest value, or the like.

The estimation system 206 may transmit, and the machine 202 may receive, an indication based on whether the performance indicator associated with the battery cell 106 is determined to be indicative of the faultiness of the battery cell 106. For example, the indication may indicate the SOH and/or the RUL responsive to a determination that the performance indicator is not indicative of the faultiness of the battery cell 106. The indication may indicate a request for additional data associated with the battery cell 106 responsive to a determination that the performance indicator is indicative of the faultiness of the battery cell 106.

Based on the indication indicating the SOH and/or the RUL, the machine 202 may update information, stored by the machine 202, indicating the SOH and/or the RUL associated with the battery cell 106. For example, the machine 202 may cause presentation of information indicating the SOH and/or the RUL on a display of the machine 202. Based on the indication indicating the request for the additional data, the machine 202 may obtain the additional data, in a similar manner in which the machine 202 obtains the charging data as described above. The additional data may indicate additional charging data associated with the charging (e.g., the same charging session from which the charging data was obtained, where a charging session may refer to a time period during which the machine 202 is continuously plugged in) and/or one or more subsequent chargings of the battery cell 106. In some implementations, the additional data may indicate additional usage data associated with one or more dischargings of the battery cell 106 (e.g., that occurred after the charging of the battery cell 106).

The additional charging data may be associated with a different SOC of the battery cell 106 (e.g., different by at least 5% or at least 10%) than an SOC of the battery cell 106 associated with the charging data. For example, during the charging of the battery cell 106 and when the battery cell 106 has a first SOC, the machine 202 may cause a first charging pulse to be applied to the battery cell 106, and the machine 202 may obtain the charging data in connection with the first charging pulse, in a similar manner as described above. Thereafter (e.g., responsive to receiving the request for additional data), and also during the same charging of the battery cell 106 when the battery cell 106 has a second SOC, the machine 202 may cause a second charging pulse to be applied to the battery cell 106, and the machine 202 may obtain the additional charging data in connection with the second charging pulse, in a similar manner as described above. Additionally, or alternatively, the additional charging data may be associated with a greater sampling frequency than a sampling frequency associated with the charging data (e.g., the charging data may be collected at 1 second intervals, whereas the additional charging data may be collected at 1 millisecond intervals).

The machine 202 may transmit, and the estimation system 206 may receive, the additional data. For example, the machine 202 may transmit the additional data to the estimation system 206 to cause the estimation system 206 to estimate an updated SOH, an updated RUL, and/or an updated performance indicator associated with the battery cell 106 based on the additional data and/or the historical data, in a similar manner as described above (e.g., using the physics-based model). Accordingly, the estimation system 206 may determine whether the updated performance indicator is indicative of the faultiness of the battery cell 106, in a similar manner as described above.

Based on determining whether the updated performance indicator associated with the battery cell 106 is indicative of the faultiness of the battery cell 106, the estimation system 206 may transmit, and the machine 202 may receive, an additional indication that indicates whether the battery cell 106 is faulty. Based on the additional indication indicating that the battery cell 106 is not faulty, the machine 202 may update information, stored by the machine 202, indicating the SOH and/or the RUL associated with the battery cell 106 (e.g., the updated SOH and/or RUL, or the initially-determined SOH and/or RUL), in a similar manner as described above. Based on the additional indication indicating that the battery cell 106 is faulty, the machine 202 may perform one or more actions.

For example, the machine 202 may transmit a notification indicating that the battery cell 106, or the battery module 104 or the battery pack 100 that includes the battery cell 106, is to be serviced. Transmitting the notification may cause presentation of the notification on a display of the machine 202. Additionally, or alternatively, the machine 202 may transmit the notification for reception by a user device associated with an operator and/or an owner of the machine 202. As another example, the machine 202 may transmit a request for servicing of the machine 202. As an additional example, the machine 202 may transmit a request for a replacement for the battery cell 106, the battery module 104, or the battery pack 100.

As indicated above, FIG. 2 is provided as an example. Other examples may differ from what is described with regard to FIG. 2.

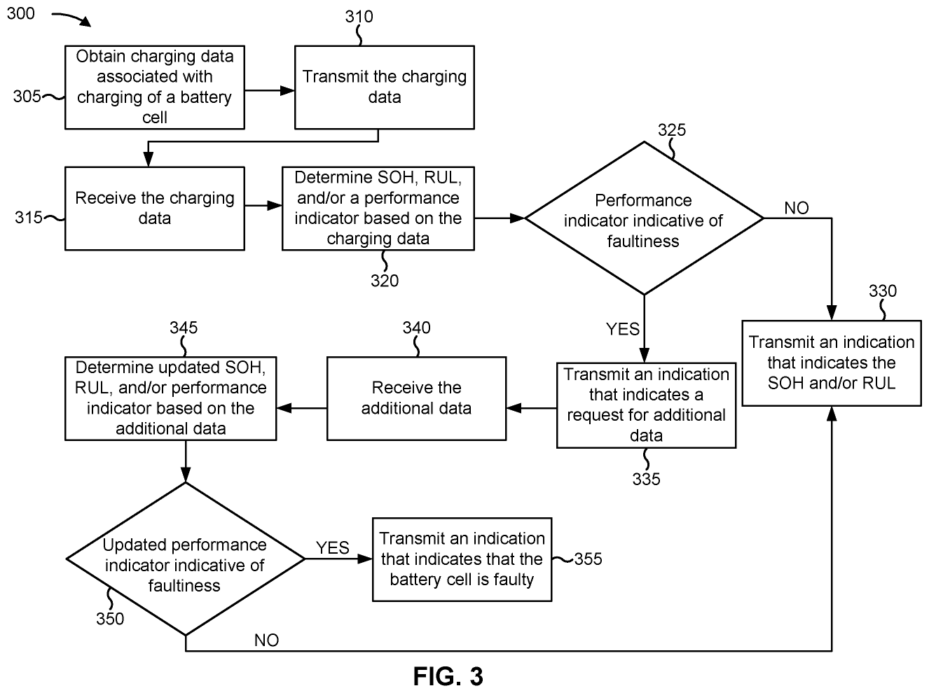

FIG. 3 is a flowchart of an example process 300 associated with battery monitoring using telematics. One or more process blocks of FIG. 3 may be performed by a device (e.g., the machine 202 and/or the estimation system 206).

As shown in FIG. 3, process 300 may include obtaining charging data associated with charging of a battery cell (block 305). For example, the machine 202 (e.g., using a memory and/or a processor) may obtain the charging data, as described herein. Process 300 may include transmitting the charging data (block 310). For example, the machine 202 (e.g., using a communication component) may transmit the charging data to the estimation system 206 (e.g., that is remote from the machine 202), as described herein. Transmitting the charging data may also include transmitting usage data, as described herein.

Process 300 may include receiving the charging data (block 315). For example, the estimation system 206 (e.g., using a communication component) may receive the charging data, as described herein. Receiving the charging data may also include receiving the usage data, as described herein. Process 300 may include determining an SOH, an RUL, and/or a performance indicator associated with the battery cell based on the charging data (block 320). For example, the estimation system 206 (e.g., using a memory and/or a processor) may determine the SOH, the RUL, and/or the performance indicator, as described herein. In some examples, the SOH, the RUL, and/or the performance indicator may be determined further based on the usage data and/or historical data. For example, process 300 may include retrieving the historical data from a storage. In some implementations, process 300 may include storing the charging data, the usage data, the SOH, the RUL, and/or the performance indicator in the storage for use in connection with a subsequent estimation.

Process 300 may include determining whether the performance indicator is indicative of a faultiness of the battery cell (block 325). For example, the estimation system 206 (e.g., using a memory and/or a processor) may determine whether the performance indicator is indicative of the faultiness of the battery cell, as described herein. Based on a determination that the performance indicator does not indicate the faultiness of the battery cell (block 325—NO), process 300 may include transmitting an indication that indicates the SOH and/or the RUL (block 330). For example, the estimation system 206 (e.g., using a communication component) may transmit the indication to the machine 202, as described herein. The indication may cause the machine 202 to update stored information indicating the SOH and/or the RUL (e.g., for presentation on a display of the machine 202). Based on a determination that the performance indicator indicates the faultiness of the battery cell (block 325—YES), process 300 may include transmitting an indication that indicates a request for additional data (block 335). For example, the estimation system 206 (e.g., using a communication component) may transmit the indication to the machine 202, as described herein. The indication may cause the machine 202 to obtain the additional data (e.g., additional charging data) and to transmit the additional data to the estimation system 206.

Process 300 may include receiving the additional data (block 340). For example, the estimation system 206 (e.g., using a communication component) may receive the additional data, as described herein. Process 300 may include determining an updated SOH, an updated RUL, and/or an updated performance indicator associated with the battery cell based on the additional data (block 345). For example, the estimation system 206 (e.g., using a memory and/or a processor) may determine the updated SOH, the updated RUL, and/or the updated performance indicator, as described herein.

Process 300 may include determining whether the updated performance indicator is indicative of the faultiness of the battery cell (block 350). For example, the estimation system 206 (e.g., using a memory and/or a processor) may determine whether the updated performance indicator is indicative of the faultiness of the battery cell, as described herein. Based on a determination that the updated performance indicator does not indicate the faultiness of the battery cell (block 350—NO), process 300 may return to block 330. Based on a determination that the updated performance indicator indicates the faultiness of the battery cell (block 350—YES), process 300 may include transmitting an indication that indicates that the battery cell is faulty (block 355). For example, the estimation system 206 (e.g., using a communication component) may transmit the indication to the machine 202, as described herein. The indication may cause the machine 202 to transmit a notification indicating that the battery cell is to be serviced.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

### INDUSTRIAL APPLICABILITY

The monitoring system described herein may be used with battery cells, and/or any battery module or battery pack that includes the battery cells, used to power a load or used for energy storage. For example, the thermal management device may be used in connection with battery cells, battery modules, and/or a battery pack used to power a machine, such as an electric vehicle or work machine. The monitoring system described herein may monitor an SOH of a battery cell, a battery module, and/or a battery pack, that powers a machine, over time to identify when the battery cell, the battery module, and/or the battery pack has reached an end of a useful life. In general, controllers on board the machine may lack the computing power needed for high-accuracy SOH estimation. SOH estimation that is less accurate may lead to the machine's battery being replaced less frequently than needed, thereby affecting a performance of the battery and the machine, and/or more frequently than needed, thereby causing excessive machine downtime and increasing maintenance costs for the machine.

The monitoring system described herein is useful for providing high-accuracy SOH estimations in connection with battery monitoring. In particular, a machine of the monitoring system may collect data relating to one or more battery cells of the machine during charging of the one or more battery cells. For example, the machine may collect the data in connection with a charging pulse applied to the battery cell(s). Data collection during charging of the battery cell(s) provides up-to-date data that is highly relevant to SOH estimation.

The machine may transmit the collected data to an estimation system of the monitoring system that is remotely located from the machine (e.g., a cloud-based estimation system). The estimation system may be provisioned with significant computing power that allows computation of high-accuracy SOH estimations. The estimation system may determine an SOH estimation using the data collected by the machine as an input to a physics-based model (e.g., based on porous electrode theory). The physics-based model may be capable of providing high-accuracy SOH estimations that otherwise may not be achievable using a data-based model. Moreover, the physics-based model may be trained using considerably less data than would be needed to train a data-based model, thereby conserving computing resources.

The high-accuracy estimations produced by the estimation system may facilitate improved monitoring of an SOH of a battery cell, a battery module, and/or a battery pack. Accordingly, a timing at which battery replacement is performed may be more precise. In this way, a battery may be replaced before a performance of the battery and/or a machine powered by the battery is affected. Furthermore, machine downtime and maintenance costs may be reduced by reducing a frequency of battery replacement.

What is claimed is:

1. A device, comprising:
one or more memories; and
one or more processors, communicatively coupled to the one or more memories, configured to:
receive, from an electric vehicle remote from the device, charging data associated with a charging of a battery cell of the electric vehicle,
the charging data indicating at least one of a voltage, a current, or a temperature associated with the battery cell during the charging;
retrieve historical data, associated with the battery cell, including one or more of: historical charging data, historical state of health (SOH) data, historical remaining useful life (RUL) data, or historical performance indicator data;
determine, using a physics-based model and based on the charging data and the historical data, one or more of: an SOH for the battery cell, an RUL for the battery cell, or a performance indicator for the battery cell;
determine whether the performance indicator is indicative of a faultiness of the battery cell; and
transmit, to the electric vehicle, an indication that indicates at least one of the SOH or the RUL, responsive to a determination that the performance indicator is not indicative of the faultiness of the battery cell, or that indicates a request for additional data associated with the battery cell responsive to a determination that the performance indicator is indicative of the faultiness of the battery cell.

2. The device of claim 1, wherein the physics-based model is based on porous electrode theory.

3. The device of claim 1, wherein the one or more processors, to receive the charging data, are configured to:
receive the charging data and usage data relating to one or more previous dischargings of the battery cell.

4. The device of claim 3, wherein the one or more of the SOH, the RUL, or the performance indicator are based on the charging data, the historical data, and the usage data.

5. The device of claim 1, wherein the one or more processors are further configured to:
receive the additional data indicating additional charging data associated with the charging or one or more subsequent chargings of the battery cell;
determine, using the physics-based model and based on the additional data and the historical data, one or more of: an updated SOH for the battery cell, an updated RUL for the battery cell, or an updated performance indicator for the battery cell;
determine whether the updated performance indicator is indicative of the faultiness of the battery cell; and
transmit an additional indication that indicates whether the battery cell is faulty based on determining whether the updated performance indicator is indicative of the faultiness of the battery cell.

6. The device of claim 5, wherein the additional charging data is associated with a different state of charge of the battery cell than a state of charge of the battery cell associated with the charging data.

7. The device of claim 5, wherein the additional charging data is associated with a greater sampling frequency than a sampling frequency associated with the charging data.

8. The device of claim 1, wherein the charging of the battery cell is a charging pulse applied to the battery cell for a time period, and
wherein the charging data includes first charging data obtained during the time period and second charging data obtained outside of the time period.

9. A method, comprising:
receiving, by a device and from an electric vehicle remote from the device, charging data associated with a charging of a battery cell of the electric vehicle,
the charging data indicating at least one of a voltage, a current, or a temperature associated with the battery cell during the charging;
determining, using a physics-based model and based on the charging data, one or more of: a state of health (SOH) for the battery cell, a remaining useful life (RUL) for the battery cell, or a performance indicator for the battery cell;
determining whether the performance indicator is indicative of a faultiness of the battery cell; and
transmitting, to the electric vehicle, an indication that indicates at least one of the SOH or the RUL, responsive to a determination that the performance indicator is not indicative of the faultiness of the battery cell, or that indicates a request for additional data associated with the battery cell responsive to a determination that the performance indicator is indicative of the faultiness of the battery cell.

10. The method of claim 9, further comprising:
storing information indicating the charging data, the SOH, the RUL, or the performance indicator in a cloud storage.

11. The method of claim 9, further comprising:
receiving the additional data indicating additional charging data associated with the charging or one or more subsequent chargings of the battery cell;
determining, using the physics-based model and based on the additional data, an updated performance indicator associated with the battery cell;
determining whether the updated performance indicator is indicative of the faultiness of the battery cell; and
transmitting an additional indication that indicates whether the battery cell is faulty based on determining whether the updated performance indicator is indicative of the faultiness of the battery cell.

12. The method of claim 11, wherein the additional charging data is associated with at least one of:
a different state of charge of the battery cell than a state of charge of the battery cell associated with the charging data, or
a greater sampling frequency than a sampling frequency associated with the charging data.

13. The method of claim 9, wherein the physics-based model is a machine learning model configured with one or more physics equations.

14. The method of claim 9, wherein the charging of the battery cell is a charging pulse applied to the battery cell for a time period, and
wherein the charging data includes first charging data obtained during the time period and second charging data obtained outside of the time period.

15. The method of claim 9, further comprising:
retrieving historical data, associated with the battery cell, including one or more of: historical charging data, historical SOH data, historical RUL data, or historical performance indicator data,
wherein the one or more of the SOH, the RUL, or the performance indicator are based on the charging data and the historical data.

16. An electric vehicle, comprising:
a battery module comprising a battery cell; and
one or more controllers configured to:
detect a charging of the battery cell;
obtain, based on detection of the charging of the battery cell, charging data associated with the charging of the battery cell,
the charging data indicating at least one of a voltage, a current, or a temperature associated with the battery cell during the charging of the battery cell;
transmit the charging data to a device remote from the electric vehicle to cause the device to estimate one or more of a state of health (SOH) for the battery cell, a remaining useful life (RUL) for the battery cell, or a performance indicator for the battery cell based on the charging data; and
receive an indication, based on the performance indicator, that indicates at least one of the SOH or the RUL, or that indicates a request for additional data associated with the battery cell.

17. The electric vehicle of claim 16, wherein the one or more controllers, to transmit the charging data, are configured to:
transmit the charging and usage data associated with one or more previous dischargings of the battery cell,
wherein the one or more of the SOH, the RUL, or the performance indicator is based on the charging data and the usage data.

18. The electric vehicle of claim 16, wherein the one or more controllers are further configured to:
obtain, based on the indication indicating the request for the additional data, the additional data indicating additional charging data associated with the charging or one or more subsequent chargings of the battery cell;
transmit the additional data to the device to cause the device to estimate, based on the additional data, one or more of an updated SOH for the battery cell, an updated RUL for the battery cell, or an updated performance indicator for the batter cell; and
receive an additional indication that indicates whether the battery cell is faulty.

19. The electric vehicle of claim 18, wherein the one or more controllers are further configured to:
transmit a notification indicating that the battery cell or the battery module is to be serviced in accordance with the additional indication indicating that the battery cell is faulty.

20. The electric vehicle of claim 16, wherein the one or more controllers are further configured to:
cause a charging pulse to be applied to the battery cell for a time period, and
wherein the one or more controllers, to obtain the charging data, are configured to:
obtain first charging data of the charging data during the time period and second charging data of the charging data outside of the time period.
